(19) United States
(12) Patent Application Publication
(10) Pub. No.: US 2022/0197599 A1
(43) Pub. Date: Jun. 23, 2022

(54) TRUE RANDOM NUMBER GENERATION FROM PRE-FORMED RERAM ARRAYS

(71) Applicant: Arizona Board of Regents on Behalf of Northern Arizona University, Flagstaff, AZ (US)

(72) Inventors: Bertrand F. Cambou, Flagstaff, AZ (US); Sareh Assiri, Flagstaff, AZ (US); Michael L. Garrett, Flagstaff, AZ (US); Saloni Jain, Flagstaff, AZ (US); Michael Partridge, Flagstaff, AZ (US)

(21) Appl. No.: 17/559,454

(22) Filed: Dec. 22, 2021

Related U.S. Application Data
(60) Provisional application No. 63/129,382, filed on Dec. 22, 2020.

(51) Int. Cl. G06F 7/58; G11C 13/00

(52) U.S. Cl. CPC G06F 7/582; G11C 13/0023

(57) ABSTRACT

The use of pre-formed arrays of memristors such as ReRAMs for true random number generation is disclosed. The method exploits the natural randomness in the large stochastic cell-to-cell variations in resistance values at low injected current in the pre-formed range. This novel TRNG scheme can be designed with three interconnected blocks: i) a pseudo-random number generator (PRNG) that is acting as an extended output function (XOF) to generate a stream of addresses pointing randomly at the array of ReRAM cells; ii) a method to read the resistance values of these cells at low injected current and convert the values in a stream of random bits; and, if needed, iii) methods to further enhance the randomness of this stream such as, but not limited to, mathematical, Boolean, and cryptographic algorithms.

### CROSS-REFERENCE TO RELATED APPLICATIONS

The present application claims priority to U.S. Provisional Application 63/129,382 entitled “True Random Number Generation From Pre-Formed ReRAM Arrays”, filed Dec. 22, 2020, the disclosure of which is incorporated herein by reference in its entirety.

### STATEMENT CONCERNING FEDERALLY-FUNDED RESEARCH

This invention was made with the support of the Government under Grant/Contract No. G1004251 awarded by the United States Air Force Research Laboratory. The government may have certain rights in the invention.

### FIELD OF THE INVENTION

The present disclosure relates to generation of true or pseudo-random number generation, which may be useful for cryptographic and authentication purposes. Specifically, the disclosure describes implementations of systems and methods that use memory arrays to generate random or pseudo-random numbers. An example of such a memory array is a resistive RAM (“ReRAM) array, which may be read using low levels of injection current.

### BACKGROUND

Cybersecurity systems and cryptography often make use of random numbers. For example, random numbers are typically used as seeds for cryptographic key generation. Thus, the development of true random number generators (TRNGs) to replace pseudo-random number generators (PRNGs) is extremely important for cybersecurity systems and cryptography. The PRNGs, which are widely available online, rely on mathematical methods that apply processing to seed values generated by, for example, a clock value or user input. These conventional PRNG's, and cryptography based on them, are subject to attack and discovery, and therefore, do not offer enough protection against sophisticated opponents with high levels of computing resources. By contrast, TRNGs may be more secure in that they may rely on the natural randomness of physical elements, preferably unclonable physical elements, the possession of which is necessary to generate the TRN. Thus, physical element based TRNG's are better than PRNG, however they usually need additional steps to enhance their randomness.

TRNGs can be generated with various memory devices such as SRAM, DRAMs, Flash RAMs, Resistive RAMS, and STT MRAM. The randomness of the physical parameters that are exploited for the design of TRNG can be due to the small manufacturing variations used to design physical unclonable functions (PUFs) that generate cryptographic keys from Challenge and Responses Pairs. However, with TRNGs, the random numbers generated at each request should be unique, while the PUF should always generate the same keys. Examples of the use of a memory array for a cryptographic key generating PUF can be found in U.S. Pat. No. 9,985,791, which is incorporated herein by reference in its entirety. That patent describes characterizing the cells of a memory array in relation to a physical parameter of the cells. The physical parameter may be a measured response of a cell in relation to one or more thresholds. For example, memory cells such as ReRAM cells, have a set voltage which is the voltage required to change the cell's stored value from low to high. Cells of a memory array may be characterized as “0” or “1” cells depending on whether a preselected set voltage sets the cell (indicating a “1” cell), or fails to set the cell (indicating a “0” cell). Thusly characterizing a memory array creates an array of “0” or “1” cell response values corresponding to array addresses. This is but one example of PUF response data that can be used to characterized addressable memory-array PUFs. Other physical parameters can be used, such as the low-current resistances of ReRAM cells, or the initial power-on state of SRAM cells.

A PUF array characterized according to the methods set forth in U.S. Pat. No. 9,985,791 may be used for cryptographic key generation and authentication. For example, a client device containing a memory device may be characterized as part of a client enrollment process, wherein the binary response values are measured and stored in a server database as a PUF image. Later, a server device in possession of the PUF image may issue a challenge to the client device, which again, is in possession of the PUF (i.e., the memory array). The challenge may contain, or be usable to obtain, a list of addresses of elements of the PUF array. Upon receiving the challenge, the client device can determine the PUF addresses contained in the challenge, and query or measure the responses of those cells. The response data can be used to generate a cryptographic key for communication with the server, which may generate a matching key with the previously stored response data in the PUF image. Alternatively or additionally, the response data can be compared, directly or indirectly, to response data retrieved from the server's PUF image to authenticate the client device by determining that the client device is in possession of the same PUF that generated the server's PUF image.

Random numbers are useful at several points in this process. For example, a server device may generate a random number, and use that number to generate a set of PUF image addresses from which to retrieve responses. That number, or the generated addresses may then be sent to the client for use in locating the same addresses in the PUF from which to measure responses. Alternatively, a client and server device may have parallel and synchronized random number generates that generate the same random numbers. Additionally, random numbers may be used in conjunction with stored or measured PUF responses to generate cryptographic keys.

PUFs may also be used to generate random numbers. Several example of the use of a PUF to generate random numbers is described in U.S. Pat. No. 9,971,566, which is incorporated herein in its entirety by reference. That patent describes a method for ternary characterization of an array of memory cells, e.g., reRAM memory cells, as having 0, 1 and X response states relative to some physical characteristic of the cell (e.g., resistance measured at some current, or range of currents). The X states identify unstable cells, which have a physical characteristic that may vary, from measurement to measurement, in a random or pseudorandom fashion. These unstable cells may be used for random number generation. Using this method of ternary characterization, stable cells in the reRAM PUF may be used for cryptographic key generation, while the unstable cells may be used for random number generation. While this is generally efficient, and a good approach, it is amenable to improvement.

### BRIEF SUMMARY

Embodiments of the invention are directed to systems and method for using arrays of pre-formed (also referred to as unformed or pristine) ReRAM cells for random number generation.

Some memory elements rely on the formation of temporary dissolvable or breakable conductive paths through otherwise insulting dielectric material to store a logic state. Such memory elements include conductive bridge RAMs (CBRAM), memristors, and resistive random access memories (ReRAMs). ReRAMs are normally used to store digital memory bits with a high resistance state (HRS) indicating one digital value and a low resistance state (LRS) indicating the opposite digital value. Conventionally, pre-formed ReRAM cells comprise two electrodes: a first electrode including active metallic material such as Cu, Ag, Ta, Al or Ti, and a second electrode include a passive metallic material such as W or Pt. The electrodes are arranged on either side of a dielectric material. Before ReRAM devices can be used as a conventional digital memory device, the devices must be pre-formed. This process involves application of a voltage across the device that is higher than some critical threshold. When such a voltage is applied, cations (e.g., Cu or other active metal ions) migrate from the first (active) electrode into the dielectric material to form one or more essentially permanent, but breakable or dissolvable, conductive paths (e.g., conductive filaments).

Pristine (i.e., unformed) ReRAM cells have extremely high resistance values, typically higher than 100 MΩ. The pre-forming process triggers an avalanche effect of the cations to form conductive filaments by ramping up the voltage across the top electrodes and bottom electrodes of each cell. The formation of these filaments results in a ReRAM cell having a low resistance state (LRS), which is typically around 5 KΩ. During a setting operation, one or more of the formed conductive paths may be broken or otherwise rendered discontinuous, resulting in the cell having a high resistance state (HRS), typically around 20 KΩ. This process is reversible, enabling the cell to be switched between its LRS and its HRS state to store one of two binary values.

The pre-forming process is irreversible, which is to say, that the conductive paths created by the forming process may be broken, but never completely removed. Thus, once ion filaments start to form in the dielectric, the electrical resistance of the device is permanently lowered by several orders of magnitude from the very high resistance of the pristine unformed device, to the relatively lower (but still higher than the LRS) resistance of the formed devices' HRS.

When Re-RAM cells are in their pre-formed, the injection of currents in the approximate range of 1 nA to 1 μA, forces the resistance values of the cells to drop to the 0.1 MΩ to 20 MΩ range; however, the resistance values return to the original high resistance values of the pristine state around 100 MΩ. This conduction under low injection currents is thus ephemeral and reversible. Inventive embodiments rely on the observation that the resistance of pre-formed ReRAM cells (defined as the ratio of voltage to the injected electric current), is unique to that cell and depends on the number, location, and physical properties, such as density of defects within the dielectric layer along with the thickness and area between electrodes, and the area of the top and bottom electrodes. Importantly, all of these parameters vary from cell to cell and device to device due to manufacturing variations. Accordingly, pre-formed ReRAM arrays have significant and random cell to cell variation in resistance, which means that each device has a unique digital “fingerprint”, i.e., the distribution of resistances across the array at one or more injection current values.

Embodiments of the invention are directed to random number generation using the resistance of addressable ReRAM cells measured under low injection currents. One embodiment includes a method of random number generation. The method includes receiving a request for a random number having a predetermined number of bits. A random number generator, in possession of a ReRAM or its image, determines a number of devices to measure (or to retrieve response data therefor) in order to yield a random number of the predetermined requested length. An address list is then generated that contains the necessary number of addresses. This address list is generated, in certain embodiments, by use of a random number generator, such as a PRNG. This random number can be processed or expanded by hashing or with an extended output function (XOF). The resistances of the selected ReRAM cells are measured (or retrieved from an image), and a bit stream is determined from the resistance measurements (or retrieved data).

In one embodiment, the random bitstream is determined by comparing the cell measurements to a median resistance value for the array, where resistances above the median are assigned a “1” and resistances below the median are assigned a “0”. In another embodiment, the random bitstream is generated by pairwise comparison of the resistance values of cells having the same address in two arrays. That is to say, the resistance value of a cell having a first address in a first ReRAM array is compared with the resistance value of a cell with the same address in a second array. If the first resistance value exceeds the second value, a “1” is generated; if not a “0” is generated. In the aforementioned embodiments, provision is made for the exclusion of unreliable cells from the cells measured to generate the random bitstream. In certain embodiments, the random bitstream is further processed to increase its randomness.

An embodiment of the invention is directed to a method of random number generation using a first addressable array of pre-formed ReRAM cells. The method involves generating an address data stream identifying a series of addresses in the array, measuring the resistance of cells having addresses in the series of addresses using an injection current, comparing the measured resistance of at least some measured cells to a value, and on the basis of the comparison, generating a random bit stream.

In certain aspects the method includes receiving a request for random number generation, the request specifying a number bit length, and generating the address data stream on the basis of the number bit length. In other aspects, the method includes generating a pseudorandom number with a pseudorandom number generator and generating the address data stream on the basis of the pseudorandom number. This may further involve segmenting the pseudorandom number into segments representing addresses in the addressable array of pre-formed ReRAM cells.

In certain embodiments, the method includes discarding at least some addresses initially included in the address data stream. For example, defective cells (cells that are unreadable, or have very high or very low resistances) can be discarded from the address data stream.

In some aspects, the method cells are measured to determined their response using the same low-level injection current for all cells. In different aspects, different injection currents are used for different cells.

In some embodiments, after cell resistances are measured, data for some measured cells is excluded. For example, cells that have a resistance equal to the median cell resistance or to the resistance of another cell to which they are to be compared may be excluded.

To generate a random bit stream, in some embodiments, measured cells may be compared to a median value of the resistance to some collection of cells (e.g., all cells in the array, all measured cells, all non-measured cells in the array, etc.). In other embodiments, each measured cell resistance is compared to another cell in the same array or a different array (e.g., a cell having the same address, but in a different array). This allows the computation of a random bit stream on the basis of pairwise cell comparison.

In certain embodiments, once a random bit stream is generated, it is further randomized. This may be done, for example, by applying an XOF operation, or by chunking the bit stream, and XORing the chunks.

Other embodiments are directed to computer systems for carrying out the aforementioned methods.

In another embodiment, a random number is generated on the basis of a stored image of a first addressable array of pre-formed ReRAM cells, the stored image containing data representing a physical response of pre-formed ReRAM cells in the array to a predetermined injection current. For this embodiment, the method includes generating an address data stream identifying a series of addresses in the array, retrieving from the image physical response data corresponding to cells having addresses in the series of addresses, and comparing the retrieved physical response data of at least some cells having addresses in the series of addresses to a value, and on the basis of the comparison, generating a random bit stream.

Embodiments directed to random number generation have certain advantages. While using unstable cells in ReRAM-based PUFs is useful, one of the limitations for those methods of TRNG is that the unstable cells tend to be a small number of the overall number of cells, typically 1-2% of the total population. By contrast, in the methods described herein use generally stable cells, which are the vast majority of the ReRAM population. This permits the generation of long random bitstreams.

Additionally, by relying on numerous different physical devices for random bit stream generation, inventive embodiments are more easily capable of demonstrating compliance with applicable standards as compared with conventional random number generations. Conventionally, the randomness of a RNG can be quantified by using a NIST test suite for random number generators such as the one described in the NIST publication 800-22 revision 1a. However, in order to follow the recommendations of international ISO/IEC 20543:2019 within ISO/IEC 19790 and ISO/IEC 15408, TRNGs should be tested a first time after their generation from the physical elements, then a second time after the enhancement steps. TRNG designed with single physical elements are usually not random enough; therefore, leveraging the randomness of the multiple cells of a memory array is attractive when they are subject to large and stochastic cell-to-cell variations.

Additionally, by using low level probe current levels when determining resistance (typically less than 1 microamp), the methods and systems described herein can perform true random number generation with minimal power usage. This is advantageous, not only from a power efficiency standpoint, but also because it reduces the chances that a side channel attack based on power monitoring or EM emissions will be capable of revealing the generated random number.

Additionally, the use of a ReRAM PUF for random number generation can be efficiently combined with methods and systems for using ReRAM PUFs for cryptographic key generation. One such combination will be described in the foregoing Detailed Description of the Preferred Embodiments.

The above features and advantages of the present invention will be better understood from the following detailed description taken in conjunction with the accompanying drawings.

### BRIEF DESCRIPTION OF THE DRAWINGS

The drawings described herein constitute part of this specification and includes exemplary embodiments of the present invention which may be embodied in various forms. It is to be understood that in some instances, various aspects of the invention may be shown exaggerated or enlarged to facilitate an understanding of the invention. Therefore, drawings may not be to scale.

FIG. 1 depicts cell-to-cell variations in a pre-formed ReRAM array with constant currents of 200 nA.

FIG. 2 depicts cell-to-cell variations with constant currents of 200 nA and two read cycles.

FIG. 3 depicts a block diagram of a simple TRNG based on pre-formed ReRAM cells.

FIG. 4 depicts a block diagram of a “median” scheme for pre-formed ReRAM-based TRNGs.

FIG. 5 depicts a block diagram of a “pairing” scheme for pre-formed ReRAM-based TRNGs.

FIG. 6 depicts a statistical test of the data stream directly generated by TRNGs using the cell pairing scheme of pre-formed ReRAM cells without removing the pairs with identical resistance values.

FIG. 7 depicts a statistical test of the data stream generated by TRNGs using the cell pairing scheme of pre-formed ReRAM cells after removing the pairs with identical resistance values.

FIG. 8 depicts a block diagram of an improved TRNG based on pre-formed ReRAM cells and additional steps enhancing randomness.

FIG. 9 depicts a step-by-step block diagram of improved TRNGs based on pre-formed ReRAM cells.

FIG. 10 depicts details of step 4 of FIG. 9 of the expansion of the levels of randomness.

FIG. 11 depicts a statistical test of the data stream generated by TRNGs using the cell pairing scheme of pre-formed ReRAM cells with a XORing by chunk of 7 bits.

FIG. 12 depicts a statistical test of the data stream generated by TRNGs using the “pairing” scheme with elimination of the pairs with identical resistance values and a XORing by chunk of 11 bits.

FIG. 13A depicts an enrollment procedure wherein a server issues processing instruction to clients having PUF arrays and stores measurements of PUF devices determined using those instructions for use in subsequent authentication of the clients, according to one embodiment.

FIG. 13B depicts a computing environment including a server and one or more clients engaging in secure communication according to certain embodiments.

### DETAILED DESCRIPTION

The described features, advantages, and characteristics may be combined in any suitable manner in one or more embodiments. One skilled in the relevant art will recognize that the invention may be practiced without one or more of the specific features or advantages of a particular embodiment. In other instances, additional features and advantages may be recognized in certain embodiments that may not be present in all embodiments.

Reference throughout this specification to “one embodiment,” “an embodiment,” or similar language means that a particular feature, structure, or characteristic described in connection with the embodiment is included in at least one embodiment. Thus appearances of the phrase “in one embodiment,” “in an embodiment,” and similar language throughout this specification may, but do not necessarily, all refer to the same embodiment. References to “users” or a “client” refer generally to individuals accessing a particular computing device or resource, to an external computing device accessing a particular computing device or resource, or to various processes executing in any combination of hardware, software, or firmware that access a particular computing device or resource. Similarly, references to a “server” refer generally to a computing device acting as a server, or processes executing in any combination of hardware, software, or firmware that access control access to a particular computing device or resource. As used herein, both a client and server refer to computing devices having at least a programmable processor in communication with non-volatile memory having stored therein computer readable and computer executable instructions operable to cause the processor to execute instructions corresponding to the method steps described in this disclosure.

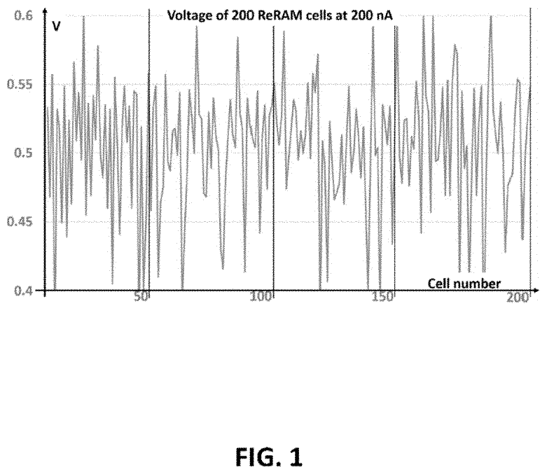

Inventive embodiments of methods and systems for random number generation are based on Applicants' recognition that pre-formed ReRAM arrays are capable of being measured to generate random bit streams. This determination was made after tens of millions of pre-formed ReRAM cells were characterized at various levels of injected currents. The stochasticity of the resulting resistance values was observed to be extremely high as reported in the example of FIG. 1, which is experimental data showing voltage drop across 200 ReRAM cells at 200 nA injection current. As can be seen, the cell to cell resistance values vary randomly in the 2-4 MΩ range.

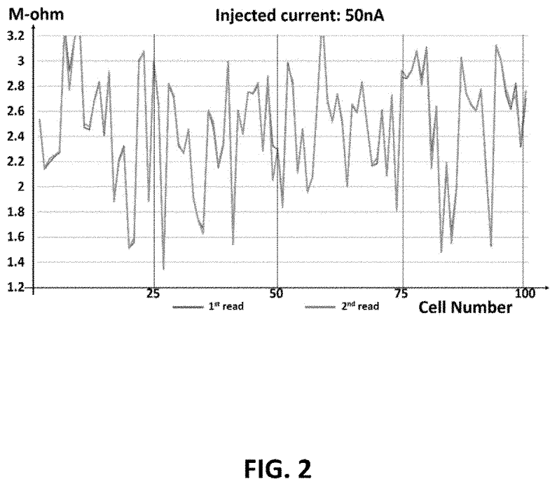

The resistance variations are mainly due to varying physical properties of each cell, while the impact of the electrical noise during the read cycles is small. This fact is confirmed by repeatability of the measurements. In FIG. 2, a set of two successive measurements of 100 pre-formed ReRAM cells is plotted. As can be seen, such measurements do not disturb the cells or change their response by performing repetitive tests. Many TRNGs have been designed by exploiting electrical noise, however the levels of randomness of such noise tends to be deterministic, as perfectly white noise is hard to find. Based on extensive characterization, it was concluded that the source of stochasticity exploited in this disclosure, the cell-to-cell variations of pre-formed ReRAMs, do not vary over time and over several read conditions.

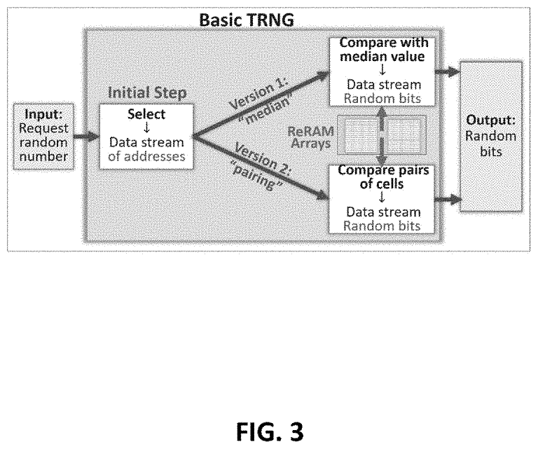

A simplified, schematic representation of a method of true random number generation using a ReRAM array is shown in FIG. 3. It should be appreciated that the method steps depicted in FIG. 3 may be carried out with any computing device in electronic communication with a ReRAM array, such that is capable of causing the ReRAM array to be probed, at the individual cell level, with probe currents. It is specifically contemplated, for example, that a computing device may be provided having a microprocessor, non-volatile memory storing computer readable instructions capable of causing the processor to execute the method steps, one or more communications interfaces, the ReRAM array, and drive and measurement electronics for sourcing the probe currents and measuring the resulting voltage drops across the cells. These elements may be located together, on the same device, or they may be located on separate devices in electronic communication with one other, for example, over a network.

Moreover, some embodiments may execute random number generation without physical possession or even electronic communication with the ReRAM array itself. In these embodiments, the ReRAM array may be pre-characterized by measuring the resistance of each cell at a number of predetermined, or along a continuum of probe current values. The resulting resistances (or equivalent information such as voltage drop) may be stored in a database along with an address of the cell being measured. This database, or image, may then be queried to return resistance values, instead of, or in addition to, measuring the ReRAM array itself.

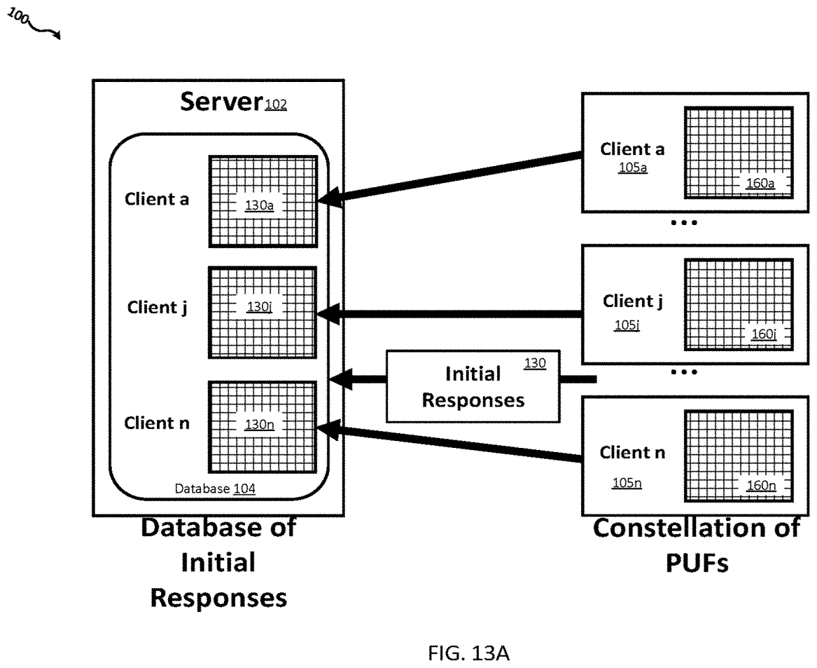

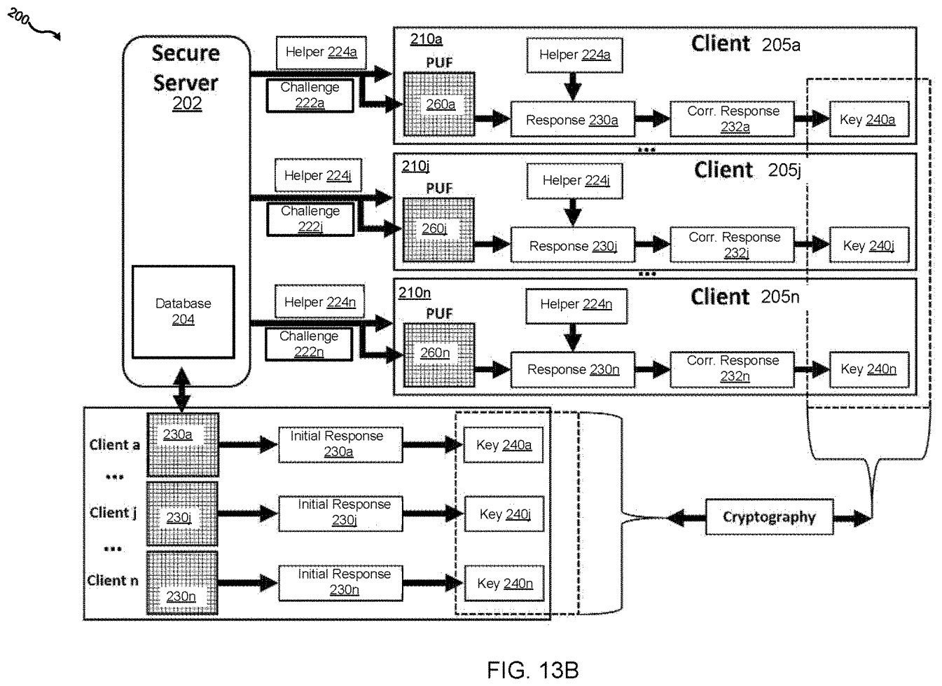

In certain arrangements, a first computing device (e.g., a client) may have the ReRAM array itself, and another computing device (e.g., a server) may store the PUF image. In these arrangements, each device is capable of generating the same random bitstream from the same input. These arrangements will be described in additional detail below in reference to FIGS. 13A-B.

Returning now to FIG. 3, a basic method of TRNG is disclosed. According to the basic method, an exemplary protocol is the following:

1) Input: New request to generate N random bits, for example N=1,000.

2) Initial Step: Select a stream of at least N addresses in the ReRAM array. For example, if the array has 1 million cells, 20 bits are needed to find the address of one cell in the array. If N=1,000, at least 20K bits are needed to find 1,000 addresses. This selection can be done by generating a stream of random numbers from a PRNG or a hash function with extended output function (XOF).

3) Output: Generate N random bits by generating random bits from the ReRAM arrays with one of the two following methods: Version 1: The “median” scheme as described below; Version 2: The “pairing” scheme as described below.

Referring now to these steps in more detail, initially an input request for RNG is received. The input request specifies that a random bitstream of a certain length N is required. Upon receipt of the request, N addresses of the ReRAM array are selected resulting in a data stream of addresses. The length of the address data stream will be N multiplied by the number of bits required to express a cell address. The addresses reflected in the address data stream may be based on a pseudo-random number generated by a PRNG. The PRNG may optionally accept as a seed input user input, such as a password, or varying input data, such as a time value generated by a clock. Alternatively, the addresses may be generated by taking some user input (e.g., a password), and hashing it or applying it as input to an extendable output function (XOF). Combinations of these techniques may be used. For example, the PRNG output may be hashed and/or XORed with some user input, time data, or other input to increase its randomness. The PRNG output, however generated, may be hashed, chunked and XORerd, or supplied to an XOF to further increase its randomness. The pseudorandom output from these processes may be used as or to generate a bit stream (the address data stream) that is segmented into words of appropriate length, where each word reflects an address of a memory element in the array. Optionally, duplicate addresses may be dropped from the address data stream.

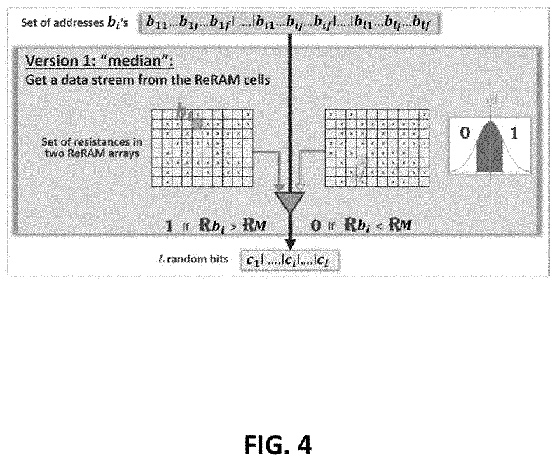

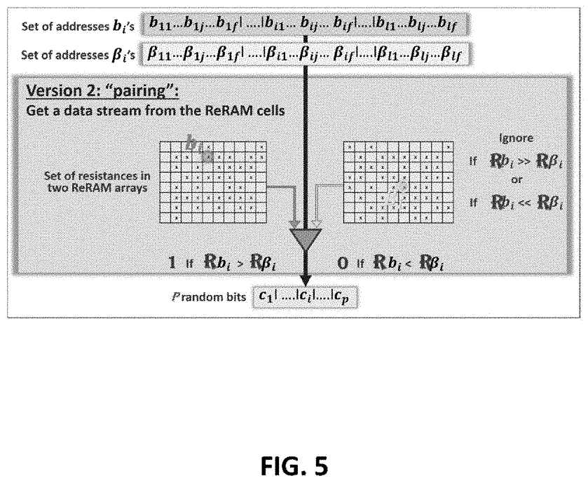

Once the address data stream is generated, the ReRAM elements are probed with a low level of injection current (preferably in the range of 1 nA to 1 μA). The probe current level may be selected randomly, for example, on the basis of the output of the PRNG used to generate the address data stream. The selected probe current is used to measure resistance/voltage of the cells identified in the address data stream. The resulting measurements are compared to some value or range of values (as set forth below in FIGS. 4 and 5), and on the basis of the comparison, are associated with a “1” or “0”. The result of this process is a random bit stream of the requested length. This random bit stream may be output, directly, or may be further processed to increase its randomness, as described below.

As presented below, the measurement of statistically significant number of pre-formed ReRAM cells feeding the suite of tests recommended by NIST is showing that the natural stochasticity of the underlying physical behavior is high enough to pass the tests without additional steps.

Design of TRNGs with the “Median” Scheme

As is set forth above, a random bit value is assigned to an address on the basis of a resistance value by comparing the measured resistance to some value. In a first example, which is schematically pictured in FIG. 4, the measured value is compared to a median value for a collection of cells. This median value may reflect the median resistance value of all cells in the array (with or without defective cells, as discussed below), the median resistance value of the cells having the addresses selected for measurement, or some other collection of cells in the array, for example, cells not selected for measurement. The median value may be calculated as part of the random bit stream generation process, or it may be predetermined and stored, which may be particularly useful if it is the median value of all cells, which may be predetermined based on a previous characterization process.

In the exemplary process of FIG. 4, to generate N random bits, L addresses of cells in the ReRAM array are needed, with L>N. Assuming that f bits are needed to express an address, a stream of f×L bits is needed for the “median” scheme. For example, if the size of the array is 1 M bit, then f=20. The reason why a stream longer than N is needed for the protocol is to handle defective cells, i.e., cells exhibiting some fabrication defect such that they cannot be read, cells with near infinite or zero resistance, or other outlier resistance values above or below some predetermined threshold. The median value M of the resistance values of the entire cell population may be known, due to previous measurements, as well as some addresses in one array that have values close to the median. The example of FIG. 4 shows an embodiment with two separate ReRAM arrays (a physical setup that is also capable of supporting the method of FIG. 5). A cell with median resistance value M is picked in one array, represented on the right side, and all other cells (the cells to be measured to create the random bit stream) are picked from the other array, on the left side.

The exemplary protocol is the following:

1) Initial Step: Eliminate the cells that are known to be defective. If less than N addresses are left, then ask for more addresses and iterate. If more than N addresses are left, then keep the first N addresses of the stream.

2) Screen: Compare the resistance value of each cell to the median of the distribution: If a cell has a resistance value lower than M, then generate a “0”. If a cell has a resistance value higher than M, then generate a “1”.

3) Output: Generate N random bits from the N cells of the ReRAM array on the left.

Design of TRNGs with the “Pairing” Scheme

In another embodiment, resistances from ReRAM cells in a first array are compared, in pairwise fashion, to resistances from cells in a second array to generate the random bit stream. Here, while “first array” and “second array” may refer to physically separate arrays, this is not a requirement. These terms may also refer to sub-arrays that are defined within a single physical device according to some partition scheme. Additionally, in the embodiment below, it is contemplated that a resistance of a cell with a first address will be compared to the resistance of a cell having the same corresponding address in another array, but this is not a requirement. Pairwise comparison can be made between the first cell having a first address, and a second cell having a second address, wherever the cell of the second address is located, either in another array or the same array. For example, in certain embodiments, a transform function may be defined that maps selected cell addresses onto other addresses in the same or a separate array, for example, by incrementing the first address's row or column number by a fixed or a varying amount.

Referring now to FIG. 5, there is shown an exemplary method where the random bit stream is generated by pairing. According this method, to generate N random bits, 2×1 addresses of cells in one or more ReRAM arrays are needed with 1>N. Assuming that f bits are needed per address, a stream of 2×f×1 bits is needed for the pairing scheme. For example, if the size of the array is 1 M bit, then f=20. The reason why a stream longer than 2 N is needed for the protocol is to handle the defective cells. The example of FIG. 5 also shows an embodiment with two separate ReRAM arrays, where cell measurements may be pulled from either or both arrays. In the specific example illustrated, a first set of addresses (the bi) is pointing at a first array located on the left side of FIG. 5; the second set of addresses (the βi) is pointing at the second array located on the right side. The protocol is the following:

1) Initial Step: Eliminate the pairs that have at least one cell known to be defective on each array. Only the pairs with two good cells are kept: If fewer than N pairs are left, then ask for more addresses and iterate. If more than N pairs are left, then keep the first N pairs of the stream.

2) Screen: Compare the resistance value of each pair of cells: a. If the resistance value of the first cell is the lower of the pair, then generate a “0”. If the resistance value of the first cell is the higher of the pair, then generate a “1”.

3) Output: generate N random bits from the N pairs of the ReRAM arrays.

Experimental Quantification of the Levels of Randomness

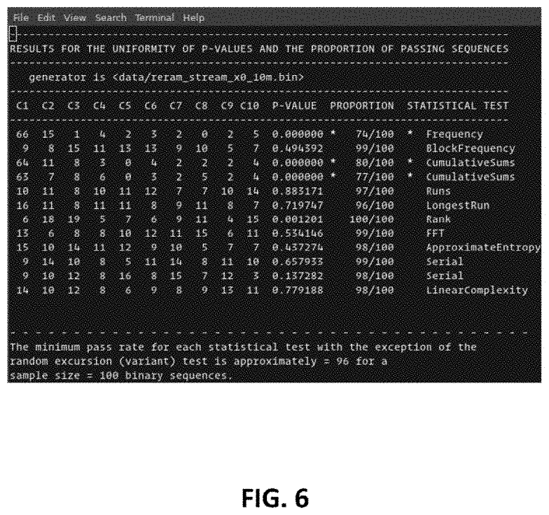

To quantify the levels of randomness of the data streams generated by TRNGs based on the methods described above applied to arrays of pre-formed ReRAMs, a set of 2 M cells was analyzed at various levels of injected currents from 200 nA to 800 nA. PRNGs were used to generate the streams of addresses, and the “pairing” scheme was used subsequently to generate streams of bits. Shown in FIG. 6 is the summary of the 12 tests performed with the suite of NIST tests on the resulting random numbers. Nine out of twelve tests are passing with scores higher than 96/100; however, three tests are failing with scores respectively at 74/100, 76/100, and 80/100. Such initial randomness directly extracted from the physical elements is encouraging, and the three low scores can be easily cured with light additional processing, according to exemplary methods described below. One of the situations that must be handled is when both cells of a pair have values exactly the same resistance value, within the resolution of the measurement hardware. Due to the limited accuracy of the measurements, 32,000 pairs are identical over a stream of 5 million pairs used to test the levels of randomness with NIST's suite. This is a relatively small number that can be fixed by using more accurate measurement techniques of the resistance of pre-formed ReRAM cells.

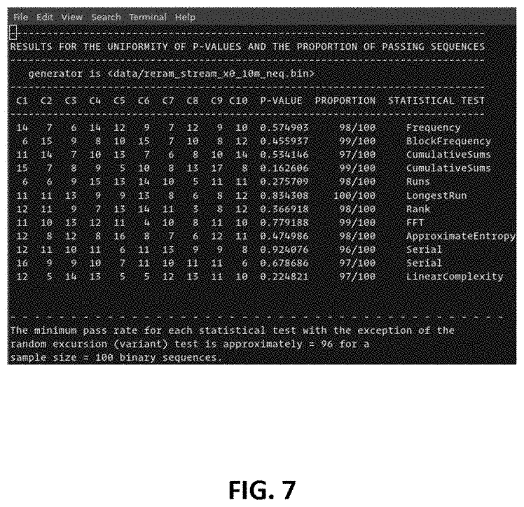

Another way to improve the levels of randomness is simply to eliminate the pairs with identical resistance value. FIG. 7 shows the summary of the 12 NIST tests to quantify the data stream, in which the pairs with identical resistances are removed from the distribution. All 12 tests are passing with an average score of 98/100 which is excellent. This suggests that a helpful additional method step is to filter the address data stream to reject address pairs where the measurement comes back showing identical resistance values, and in such cases, to revise the number of needed addresses, and increase the address data stream to reflect new pairs accordingly.

All additional statistical analysis of the levels of randomness obtained with various versions of TRNGs based on pre-formed cells with the suite of NIST tests resulted in similar satisfactory results. This confirms the excellent stochasticity of the physical parameters driving such TRNGs.

Design of Enhanced Versions of TRNGs

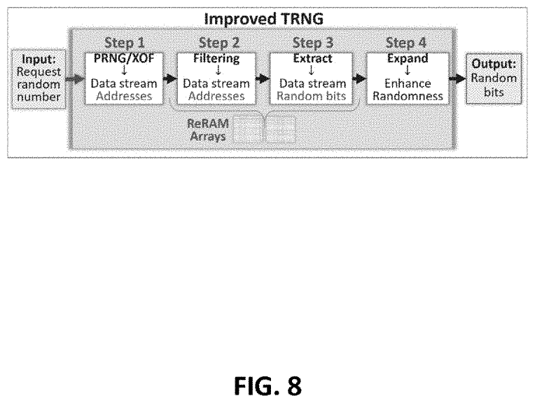

The random bitstreams generated by the methods described above may be improved by additional process steps, which will now be described in reference to FIGS. 8-10. An exemplary general method protocol for an enhanced method includes the following steps:

1) Input: New request to generate N random bits, for example N=1,000.

2) Step 1: Select a stream of at least N addresses in the ReRAM array. For example, if the array has 1 million cells, 20 bits are needed to find the address of one cell in the array. If N=1,000, at least 20K bits are needed to find 1,000 addresses. This selection can be done for example, by generating a stream of random numbers from a PRNG or a hash function with extended output function (XOF) or a combination of.

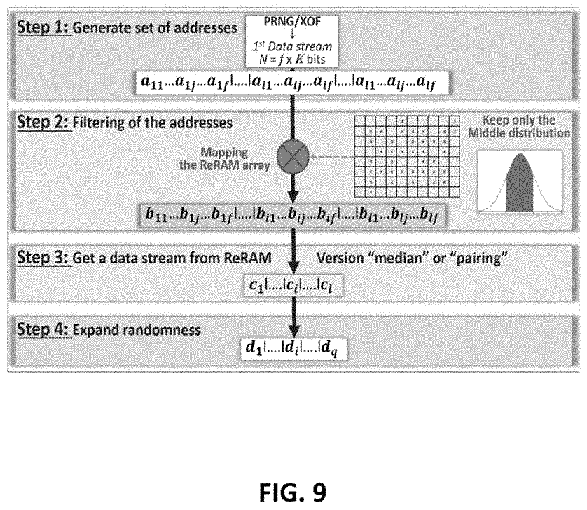

3) Step 2: Filtering the set of addresses to keep only the addresses in the arrays that are desirable for the TRNG. Example of addresses that are excluded are: a) Defective cells due to catastrophic defects during fabrication; b) Cells with resistance values too far from the median value; c) In case of the “median” scheme, elimination of the cells that have a resistance value precisely equal to the median value; and d) In case of the “pairing” scheme, elimination of the pairs with two cells have the same exact resistance value. One such filtering scheme is shown in FIG. 9, where illustrates the rejection of addresses with resistance values above and/or below a predetermined threshold, such that only addresses returning resistance values distributed relatively close to the median value are retained. Again, it is contemplated that filtering is part of an iterative process where, if filtering results in fewer addresses than are needed to return N random bits, additional addresses are selected until enough usable addresses have been identified to return N random bits.

4) Step 3: Generate N random bits by generating random bits from the ReRAM arrays with one of methods such as the “median” scheme or the “pairing” scheme as described previously.

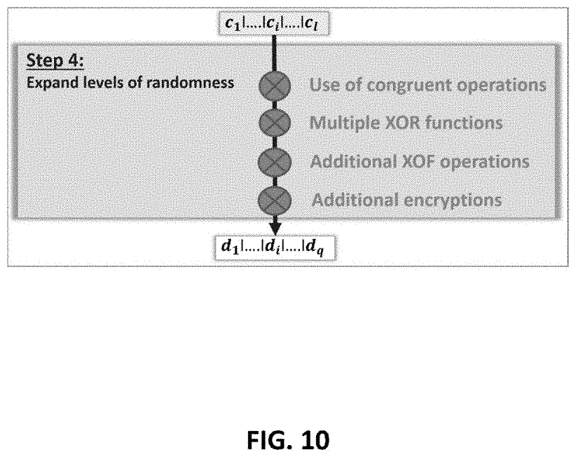

5) Step 4: Enhance randomness by using additional schemes (see FIG. 10), such as congruent operations, XORing of the data stream by blocks of bits, additional XOF, multiple encryption schemes, transpositions, etc.

6) Output: The N random bits.

As is set forth above at step 4, a random bitstream generated by the methods described herein may be subject to further processing in order to further enhance randomness. Some exemplary post-processing techniques are shown in FIG. 10. In order to quantify the effect of some of these additional steps to enhance randomness, the two random numbers generated from arrays of pre-formed ReRAM cells were subject to additional XORing operations, and the randomness of resulting bit streams was evaluated.

### Example 1

A first stream of random numbers that fails three out of twelve NIST tests was handled in the following way:

1) Step 1: Group the streams of random bits by chunk of 7 bits.

2) Step 2: Add the 7 bits of each chunk modulo 2 to get one resulting bit: a 0 or a 1. This operation is equivalent to the XORing of the 7 bits. If the numbers of “1”s is odd, the resulting bit is a “1”; if even, then the resulting bit is a “0”. The level of randomness is enhanced by such operation.

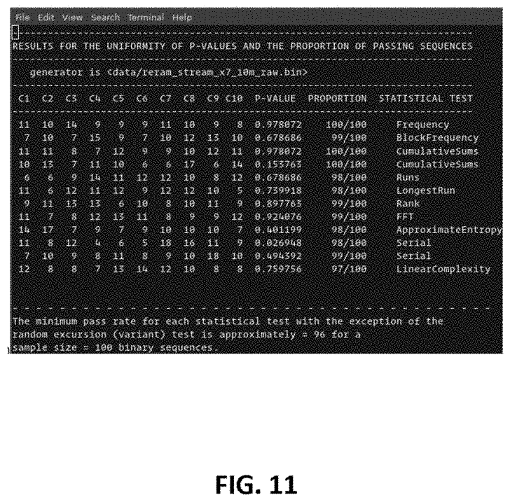

The results of this process, which are shown in FIG. 11, are excellent. All twelve NIST tests are passed, and the average score is 98.75/100 which is well above the threshold. It is also noticeable that the three failed tests above are now passing with the score of 100/100. The XORing operations are fast and consume low power, however the latency of such a scheme is by definition seven times slower per bit generated; in order to generate 1,000 bits, 7,000 bits need to be generated from the ReRAM cells. An optimized scheme is achieved by XORing smaller chunk of bits, which has enough levels of randomness to pass the tests and better latencies.

### Example 2

The second stream of random numbers that pass all twelve NIST tests with an average score of 98/100 was handled in the following way:

1) Step 1: Group the stream of random bits by chunk of 11 bits.

2) Step 2: Add each chunk modulo 2 to get one resulting bit: a 0 or a 1. This operation is equivalent to the XORing of the 11 bits. If the numbers of “1”s is odd, the resulting bit is a “1”; if even, then the resulting bit is a “0”. The level of randomness is enhanced as multiple combinations of 11 bits yield the same resulting bits.

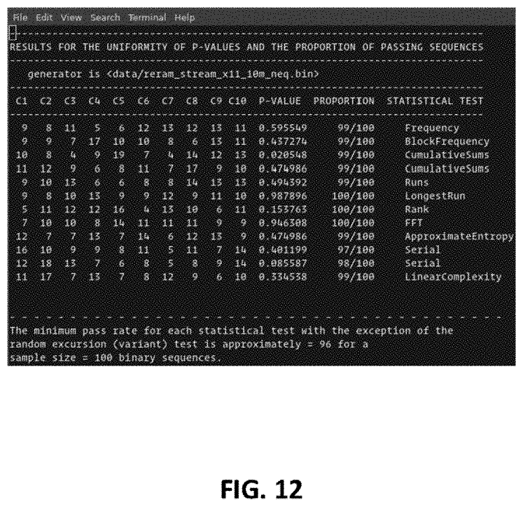

The twelve tests, as shown in FIG. 12, now pass with an average score of 99/100 which is even better than what was reported without XORing. Ten of the twelve tests score 99/100 or higher which is as good as one can expect considering the length of the data stream generated by the TRNG. However, the 98/100 score before XORing is already good enough, and the need to further enhance randomness is marginal.

The embodiments described above have been directed to using arrays of ReRAM memory cells as TRNGs. The concepts described herein, however, may be extended to other physical arrays of devices that demonstrate randomness, and in particular, to arrays of devices that demonstrate random distributions of resistance, such as memristor arrays generally.

Additionally, in the embodiments described above, the application of a probe current to measure voltage drop is described. With knowledge of the applied probe current and a measurement of voltage drop across the ReRAM element, its resistance may be calculated. But it should be appreciated that a random bit stream may be generated on the basis of either measured voltage or calculated resistance.

Additionally, in the embodiments above, it is contemplated that a constant probe current value in the range of 1 nA to 1 μA is selected and used for all cell measurements, but this should not be considered limiting. In alternative embodiments, multiple probe currents may be selected and used for different cells. In yet further embodiments, multiple probe currents may be used for the same cell. By way of example only, when the address data stream is generated, it may be segmented into words having sufficient bit length to specify both a cell address and a cell probe current to apply to measure that cell. In these cases, it may be desirable to not exclude duplicate cell addresses since the duplicate cells may be measured with a different current thereby preserving randomness. When these multiple current techniques are applied using the median comparison method described above, the median cell resistance value may be computed using the variable currents specified in the address data stream. When these multiple current techniques are applied during the pairing method described above, the same probe current may be used to measure each cell in a designated pair of cells of being compared.

Additionally, while the embodiments above discuss measuring ReRAM cells by a device in possession of or in electronic communication with one or more arrays of ReRAM cells, this is not a requirement. As stated above, one or more arrays of ReRAM cells may be exhaustively characterized in advanced by measuring and storing resistance values in a database (i.e., an “image”) that associates the resistance measurements with the addresses of the cells. This may be done for a number of probe current values. The methods above may, then, be employed on images of the ReRAM arrays rather than the arrays themselves. These techniques may be useful for permitting two devices, one in possession of the ReRAM array, and another in possession of its image, to generate the same pair of random numbers in parallel. This arrangement may be especially helpful in permitting generation of cryptographic key pairs to be used for encrypted communication between the two devices.

As one example of the arrangement above, a first computing device, e.g., a server device, is in possession of an image of a ReRAM array, reflecting resistance measurement previously taken of all cells in the array stored in association with their addresses. Another computing device, e.g., a client device, is in possession of the ReRAM array itself, which was previously measured. One device may send a handshaking message to the other device to initiate generation of a random number. The handshaking message may include user input, such as a password or user name, or a time stamp. In one embodiment, the handshaking message, components thereof, of data derived therefrom, is used as seed input to a PRNG process, which is used to generate an address data stream, as described above. The PRNG process should be the same at both the client and server device to ensure that the same addresses are generated. In other embodiments, the handshaking message itself is used to generate the address lists, e.g., by hashing, applying an XOF function, or chunking and XORing. The handshaking message may also be something as simple as a “request” for random number generation specifying a bit length, which prompts the receiving device to generate an address data stream according to any of the methods described above. Any arrangement that results in parallel address data streams being generated on both the client and server sides is within the scope of the invention.

Once each device has generated an address data stream, the ReRAM devices corresponding to the addresses are measured (at a first device), or are retrieved from the image (at a second device), and a pair of random bit streams is generated according to the methods set forth above. The result of this process is two parallel (and ideally identical) random bit streams at each device. These can be used by each device as or to generate matching encryption keys by known methods to ensure secure communications between the devices. Additionally, one random bit stream may be sent from one device to the other where it is received and compared to the native copy to authenticate the sending device.

The ReRAM random number generation methods described above may be combined with other encryption schemes, including keyless schemes, which also rely on arrays of pre-formed ReRAM cells.

Conventional systems and methods for secure communication frequently rely upon encryption of messages using encryption keys which may be symmetrical or asymmetrical (e.g., in public key encryption schemes). Such key-based encryption schemes have disadvantages. First keys must be generated and stored by various parties, introducing the possibility that the keys may be compromised by a malicious party. Additionally, key-based encryption schemes may be vulnerable to brute force attacks wherein a malicious party may discover the key given access to a message encrypted with that key.

Also, conventional systems and methods for challenge-response authentication have disadvantages. For example, when the server and the client communicate over an insecure channel, both the challenges and the challenge responses may be intercepted, providing information which may be useful to an attacker.

Embodiments disclosed herein address these and other shortcomings by using physical unclonable function generators (APGs) to generate unique, difficult to intercept challenge-response pairs, and eliminate the need to exchange keys over potentially insecure communication channels, thereby improving security. PUF generators can be thought of as “wallets” of keys that are addressable though a handshake with a server. Rather than exchanging keys through insecure communication channels, both parties exchange (or independently access) sets of processing instructions, which may include randomly generated PUF addresses, and generate the keys directly from their “wallets.” Thus, large numbers of keys can be made available for use with cryptography, without requiring large exchanges of information over communication channels which may weaken security and/or impose performance penalties.

In the context of this disclosure, a processing instruction is any information used to cause an APG to produce an expected response (sometimes referred to as a “challenge response” in the context of authentication systems) corresponding to that information by measuring one or more PUF devices. Processing instructions may be used to cause an APG to access devices (or ranges of devices) in an array of PUF devices belonging to the APG. Along these lines, a processing instruction may be input supplied to an APG which is used to produce a response having one or more expected values which depend upon characteristics' of the PUF array belonging to the APG to which the processing instruction is issued. The appropriate response may be derived from those characteristics using instructions stored by the APG or other processing circuitry, received by the APG or other processing circuitry and/or additional information supplied to the APG or other processing circuitry (such as a password of a user). In one simple non-limiting example, a processing instruction might simply cause an APG to measure a physical response or characteristic of devices of a PUF array at a specified address or range of addresses. In other non-limiting examples, a processing instruction processing instruction might include instructions to perform a mathematical, logical, or other operation(s) on those values.

An array of addressable PUFs can be used as an addressable wallet of cryptographic keys. The PUFs are the “fingerprints” of microelectronic components such as the ReRAM memory devices discussed herein. During enrollment, the fingerprint of the PUF of the client device is memorized by the server in the form of a look up table, or cryptographic table. Assuming that the PUF is reliable, the same reading can be extracted on demand. Error matching and correcting methods can be used to address potential small mismatches between the stored expected response data and the measured challenge response. This may be advantageous when the PUF is subject to aging, temperature changes, or environmental variations. A processing instruction (e.g., a range of PUF addresses) generated by the server side may become a “public key” that is openly shared between communicating parties. The processing instruction may be hashed with an additional password, PIN code, and/or biometric data (e.g., fingerprint, vein pattern, or retinal data). In some embodiments, both a server and a client device (or other such devices) that share access to data representing characteristics of a PUF itself can independently generate encryption key pairs according to any suitable asymmetric encryption scheme. While such asymmetric key pairs frequently referred to as “public” and “private” keys, it should be noted that the embodiments herein enable the use of such key pairs without the need for a so-called “public” key to be published or made publicly available in any way, while still realizing the other known benefits of public/private key encryption.

Embodiments disclosed herein are directed to ReRAM based APGs. As is set forth above, such devices are usable, for example, to enable secure authentication and identification of client devices and for generation of keys or key pairs for cryptography, as in a public key infrastructure (PKI).

In many of the embodiments disclosed herein, the APG includes an addressable ReRAM in its pristine, or pre-formed state. The PUF challenge for such a device may be a set of ReRAM cell addresses, a target probe or interrogation current for each cell, and additional parameters such as temperature. When the measurement conditions are applied to the PUF, a challenge response is generated. An exemplary response for PUFs disclosed herein is a resistance measurement. The APG may be characterized by, in a secure environment, applying a predetermined range of probe currents to each cell of an unformed ReRAM memory array, and recording the challenges and the responses in a table. The table may then be used to authenticate future communications with the device carrying the APG. Challenge-response pairs may also be used, by an APG carrying client device and the server, to generate cryptographic key pairs. For example, devices in communication may treat a challenge as a public key, and a PUF response as a private key, using any suitable PKI such as Rivest-Shamir-Adleman cryptosystein (RSA), DSA, and Elliptic Curves (ECC).

In such schemes, the challenge, or range of addresses, may be thought of as a shared public key, which may be transmitted from a server to a client. Preferably, this transmission occurs securely, with the address information being encrypted. The client may generate a private key by interrogating the PUF devices at the specified range of addresses, and measuring the response (e.g., the resistance) of those devices. That measurement may be used to produce a bit stream, which may be used to generate a private key. The server side device, which has previously enrolled the client device and generated a cryptographic table of the responses of the client's device, may generate the same private key. The two devices may then use their keys to encrypt and decrypt shared communications.

According to various embodiments, a PUF-enabled authentication/communication protocol includes the following stages: (1) Enrollment, (2) Handshaking, and (3) Authentication/Encryption Key generation. FIG. 13A is a conceptual block diagram of a computing environment 100 using unformed ReRAM arrays on client devices as PUFs according to inventive embodiments. This same computing environment may be used to implement the TRNG generation methods described above. The environment 100 includes a server 102 and client devices, hereinafter clients 105 (represented by clients 105a, 105j, and 105n). The sever 102 manages a database 104 which may be stored in memory of the server 102. The database 104 stores a set of initial challenge responses 130, which may be generated in response to challenges issued by the server 102 to the clients 105, each of which may respond to the challenges by accessing a respective PUF array 160 represented by the PUF arrays 160a, 160j, and 160n belonging to clients 105a, 105j, and 105n. PUF arrays 104a, 105j, and 105n may be pristine (unformed) ReRAM arrays, with individual addressable memory cells. The server 102 may be otherwise provided with information suitable to generate the initial challenge responses 130.

A PUF array 160 may form parts of an addressable PUF generator (APG), which may contain additional processing circuitry and execute instructions for generating challenge responses. For example, an APG may include a processor or microcontroller, network communications interface, non-volatile memory for storing data and instructions executable by the processor, and circuitry sufficient to generate probe current, measure voltage drop or resistance of ReRAM cells in accordance with received instructions, and digitally encode the resulting resistance data, thereby generating a PUF response. These measurements may be done directly or indirectly, and may involve current-voltage measurements and a calculation of resistance.

Enrollment is performed for each client 105 in a secure environment. Exemplary enrollment processes are described in additional detail below, but at a high level, enrollment includes the steps of selecting ReRAM addresses, applying a probe current, measuring the resulting resistance of the selecting ReRAM cells, and storing the addresses, the probe current and the resistance in the server database 104, for example, in a challenge table. After enrollment, the constellation of clients 105 may operate in an insecure environment and communicate with each other over public networks. For example, a server may authenticate an enrolled client by transmitting a challenge, receiving the client-generated response, and comparing the response to the initial response stored in database 104. Alternatively, challenges and responses may be used, themselves or in combination with additional information for cryptographic key generation. Various means of secure cryptographic communication using PUFs, which are usable in combination with the embodiments disclosed herein, are disclosed in, for example, U.S. patent application Ser. Nos. 16/416,028, 16/492,572, and 16/818,807, all of which are incorporated herein by reference in their entirety.

FIG. 13B illustrates a simplified example embodiment 200 of clients 205 (i.e., clients {205a, . . . 205j, . . . 205n}) having APGs 210 (i.e., APGs {210a, . . . 210j, . . . 210n}) belonging to a client 205, interacting with a server 202 according to embodiments disclosed herein. Each APG 210 includes a PUF array 260 (i.e., APGs {260a, . . . 260j, . . . 260n}) which may be accessed by a microcontroller or other processing circuitry of each client 205. The PUF array 260 of a client 205 is an array of electronic or other devices with measurable physical characteristics, configured in an addressable array similar to an addressable memory device such as RAM or ROM chip. In many embodiments described herein PUF array 260 is an array of unformed memory cells in which breakable conductive paths may be induced. Examples include a ReRAM array, a memristor array, and CBRAM array. Due to small variations which occur during semiconductor manufacturing or other manufacturing processes, each PUF device (and hence each PUF array 260) may be unique, even if the PUF arrays are mass-produced by a process designed to produce nominally identical devices. The PUF array 210 (shown as a 2D-array of cells) of a client 205 may be accessed by the client 205 which receives challenges 222 (originating in this example from the server 202). The APG 210 responds by to challenges 222 by generating responses 230 using measured characteristics of one or more PUF devices within the PUF array 260 identified by the challenge 222 or derived from it using instructions stored by the APG 210.

Each client 205 (represented by “Client a”, “Client j”, and “Client n”, i.e., clients 205a, 205j, and 205n shown) has an APG 210 containing a PUF array 260 that is unique to that client 205. The APG 210 of a client 205 may be used to generate numerous responses 230 (i.e., responses {230a, . . . 230j, . . . 230}) unique to that client 205. These responses 230 cannot be replicated by an attacker without physical access to the PUF array 260. During the Enrollment stage, the server 202 may obtain the initial responses 230 for each client 205 by generating a plurality of challenges 222 and storing responses 230 to those challenges 222 generated by each APG 210 in a database 204. Alternatively, the server 202 may be otherwise supplied with characteristics of each PUF array 260 sufficient to generate the expected responses 230. The microcontroller 220 may include instructions to combine information from the challenge 222 with additional information (such as a user password 223) and pass the combination through a hash function 221 the result to produce the address 225 (or range of addresses) within the PUF array 260 to measure in order to generate the proper response 230.

After the clients 205 are enrolled with the server 202, embodiments disclosed herein may be utilized to authenticate the client 205 and produce an encryption key which the server 202 and client 205 may use to communicate securely. First, the server 202 and a client 205 (such as “Client j” shown in FIG. 2A) enter the Handshaking stage. In the Handshaking stage an objective is for the server 202 to transmit the information needed to identify a particular portion of the PUF array 260 of the client 205. Both the server 202 and the client 205 can independently produce a response to the challenge: the server can lookup information about the PUF array 260 obtained during enrollment (or otherwise supplied to the server 202) and the client 205 can retrieve the same information by using the APG 210 to access the PUF array 260.

During Handshaking, the server 202 issues a challenge 222 to the APG 210 of the client 205. This challenge 222 is used by the APG 210 to identify the portion of the devices belonging to the PUF array 260 to access. This challenge 222 may be a random number generated by any of the TRNG procedures described above operating on server's PUF image. In some embodiments, the server 202 and the client 205 may have access to the same random number generator or may have synchronized random number generators. In some embodiments, each device generates the same random number by the TRNG processes described above, operating on each device's ReRAM PUF or the corresponding PUF image. In such embodiments, the server 202 does not need to transmit the challenge 222 to the client 205 in order for the client 205 to generate the challenge response 230 using the APG 210.

In some embodiments the ability of the client 205 to generate the challenge response 230 may be protected by a password. In such embodiments, the address specifying which device(s) in the PUF array 260 to access may be produced by combining the challenge 222 with the password. As a non-limiting example, the client 205 may input the password and the challenge into a hashing function to produce the address in the PUF array 260. As an example, if the PUF array 260 is represented as a two-dimensional array containing 256 rows and 256 columns, 8 bits of the message digest can be used to find the first coordinate X in the PUF array 260; the following 8 bits can be used to find the second coordinate Y.

The measurement of characteristics of individual PUF devices may not be perfectly deterministic. As discussed above, where PUF 260 is a ReRAM, there may be 10% to measurement to measurement variation in resistance at a given injection current, owing primarily to temperature variation. As part of the Handshaking process, the server 202 may send additional information to the client 205 for use in making generation of the challenge response 230 more reliable. The helper instructions 224 (i.e., helper instructions {224a, . . . 224j, . . . 224n}) may include a checksum or other error-correcting information for use with error-correcting codes, or other information or instructions used in response generation schemes to be discussed later below. Upon receiving the challenge response 230, the APG 210 may use the helper instructions 224 to generate corrected responses 232 (i.e., corrected responses {232a, . . . 232j, . . . 232n}). Use of the helper instructions 224 and other methods of improving the reliability of the APG 210 will be discussed further below. The corrected responses 232 may be used directly as encryption keys 240 or may otherwise be used to derive the encryption keys 240. The server 202 may similarly independently produce the encryption keys 240 using the initial responses 230 stored in the database 204. The server 202 and the client 205 may then communicate securely by encrypting messages using the shared encryption keys 240

The server 202 can authenticate a client 205 by issuing the challenge 222 to the client 205 and then comparing the corrected challenge response 232 generated by APG 210 with the initial response to that challenge stored by the server 202 for that client 205 (e.g., initial challenge responses 230) or determine that the corrected challenge response 232 is consistent with the initial challenge response 230 by comparing information derived from the corrected challenge responses 232 with information derived similarly by the server 202 from one of the initial challenge responses 230 corresponding to the challenge 232 issued by the server. The server 202 may require that the corrected response 232 is identical to the expected response to the challenge 222 (i.e., the initial response 230 corresponding to the challenge 222) in order to authenticate the client 205. Alternatively, the server 202 may accept a corrected response 232 with a Hamming distance (or a value of another distance metric) less than a predetermined maximum value from the expected response as evidence that the challenge response 230 is consistent with the expected response. For example, the server 202 may infer that the client 205 has generated a response which differs by less than a predetermined maximum number of symbols from the initial response 230 and determine that the challenge response 230 is consistent with the initial response 230 (i.e., was generated by a client 205 in possession of the same PUF array used to obtain the initial response 230). When the CRP error rates are relatively low, the responses can be used as part of authentication protocols. In such cases, Hamming distances between responses and the expected responses as large as 10% of the total response length may still be used to provide acceptable false-accept and false-reject rates (FRR and FAR). When the CRP error rates are too high, the use of error-correcting methods may be used to improve both FAR and FRR.

While the description of cryptographic methods and protocols above has made reference primarily to ReRAM PUFs, it should be appreciated that the methods and protocols are equally applicable to PUFs based on other memory devices using dissolvable conductive pathways such as Conductive Bridge RAMs (CBRAM) and Memristors.

The described features, advantages, and characteristics may be combined in any suitable manner in one or more embodiments. One skilled in the relevant art will recognize that the circuit may be practiced without one or more of the specific features or advantages of a particular embodiment. In other instances, additional features and advantages may be recognized in certain embodiments that may not be present in all embodiments.

Reference throughout this specification to “one embodiment,” “an embodiment,” or similar language means that a particular feature, structure, or characteristic described in connection with the embodiment is included in at least one embodiment. Thus, appearances of the phrase “in one embodiment,” “in an embodiment,” and similar language throughout this specification may, but do not necessarily, all refer to the same embodiment.

1. A method of random number generation using a first addressable array of pre-formed ReRAM cells, comprising:
generating an address data stream identifying a series of addresses in the array;
measuring the resistance of cells having addresses in the series of addresses using an injection current;
comparing the measured resistance of at least some measured cells to a value, and on the basis of the comparison, generating a random bit stream.

2. The method of claim 1, further comprising receiving a request for random number generation, the request specifying a number bit length, and generating the address data stream on the basis of the number bit length.

3. The method of claim 1, wherein generating an address data stream comprises generating a pseudorandom number with a pseudorandom number generator and generating the address data stream on the basis of the pseudorandom number.

4. The method of claim 3, wherein generating the address data stream on the basis of the pseudorandom number comprises segmenting the pseudorandom number into segments representing addresses in the addressable array of pre-formed ReRAM cells.

5. The method of claim 1, further comprising discarding at least some addresses initially included in the address data stream.

6. The method of claim 5, wherein discarding at least addresses comprises identifying addresses corresponding to defective cells.

7. The method of claim 1, wherein measuring the resistance of cells having addresses in the series of addresses using an injection current comprises using the same injection current to measure the resistance of all cells having addresses in the series of addresses.

8. The method of claim 1, wherein measuring the resistance of cells having addresses in the series of addresses using an injection current comprises using a plurality of injection currents to measure the resistance cells having addresses in the series of addresses.

9. The method of claim 1, further comprising, after the measuring the resistance of cells having addresses in the series of addresses using an injection current, excluding measured resistance values for at least some of the measured cells prior to comparing the measured resistance of at least some measured cells to a value, and on the basis of the comparison, generating a random bit stream.

10. The method of claim 1, wherein comparing the measured resistance of at least some measured cells to a value comprises comparing the measured resistance of at least some measured cells to a median resistance of a plurality of cells in the array.

11. The method of claim 1, wherein comparing the measured resistance of at least some measured cells to a value comprises performing a pairwise comparison of the measured resistance of the at least some measured cells to resistances of cells in another set of ReRAM cells.

12. The method of claim 11, wherein the another set of ReRAM cells is located in a second addressable array of pre-formed ReRAM cells.

13. The method of claim 1, further comprising generating a further randomized bit stream by subjecting the bitstream to one or more XOR functions or XOF operations.

14. A system for random number generation, comprising a processor, a non-volatile memory coupled to the processor and an addressable array of un-formed ReRAM cells coupled to the processor, the memory storing computer readable instructions operable to cause the processor to:
receive a request to generate a random number of a predetermined bit length;
generate an address data stream identifying a series of addresses in the array, the series of addresses in the array including a number of addresses selected on the basis of the predetermined bit length;
measure the resistance of cells having addresses in the series of addresses using an injection current;
compare the measured resistance of at least some measured cells to a value, and on the basis of the comparison, generating a random bit stream.

15. The system of claim 14, wherein the memory stores instructions further operable to cause the processor to:
generate the address data stream on the basis of the pseudorandom number and segment the pseudorandom number into segments representing addresses in the addressable array of pre-formed ReRAM cells.

16. The method of claim 14, wherein the memory stores instructions further operable to cause the processor to:
compare the measured resistance of at least some measured cells to a median resistance of a plurality of cells in the array.

17. The method of claim 16, wherein the plurality of cells in the array comprises a plurality of cells identified in the address data stream.

18. The method of claim 14, wherein the memory stores instructions further operable to cause the processor to:
perform a pairwise comparison of the measured resistance of the at least some measured cells to resistances of cells in another set of ReRAM cells.

19. A method of random number generation using a stored image of a first addressable array of pre-formed ReRAM cells, the stored image containing data representing a physical response of pre-formed ReRAM cells in the array to a predetermined injection current, comprising:
generating an address data stream identifying a series of addresses in the array;
retrieving from the image physical response data corresponding to cells having addresses in the series of addresses;
comparing the retrieved physical response data of at least some cells having addresses in the series of addresses to a value, and on the basis of the comparison, generating a random bit stream.

20. The method of claim 19, wherein comparing the retrieved physical response data of at least some cells having addresses in the series of addresses to a value comprises performing a pairwise comparison of the retrieved physical response data of the at least some cells to physical response data of other ReRAM cells stored in the image.
